(19) United States
(12) Patent Application Publication
(10) Pub. No.: US 2017/0263423 A1
(43) Pub. Date: Sep. 14, 2017

(54) DEVICE EQUIPPED WITH AN ION BEAM SOURCE FOR COATING A SUBSTRATE IN A VACUUM CHAMBER

(71) Applicant: LO Laseroptik GmbH, Garbsen (DE)

(72) Inventor: Wolfgang Ebert, Garbsen (DE)

(21) Appl. No.: 15/259,069

(22) Filed: Sep. 8, 2016

(30) Foreign Application Priority Data
Mar. 8, 2016 (DE) 20 2016 101 274.0

(51) Int. Cl. H01J 37/34; C23C 14/50

(52) U.S. Cl. CPC H01J 37/3464; C23C 14/50; H01J 37/3476

(57) ABSTRACT

A device has an ion beam source for coating at least one substrate in a vacuum chamber, which chamber has an inlet that is closable in a pressure-tight manner using a closure apparatus and through which the at least one substrate can be fixed in the vacuum chamber in a substrate holder in a substrate holder receptacle, and can be removed therefrom once the coating process has finished, wherein the substrate holder, together with the substrate, in the substrate holder receptacle is designed to be reversibly movable in a translational manner inside the vacuum chamber, between turning points that are in particular settable, using a motor-drivable transport apparatus of the device.

### CROSS-REFERENCE TO RELATED APPLICATIONS

Priority is claimed to German Patent Application No. DE 20 2016 101 274.0, filed on Mar. 8, 2016, the entire disclosure of which is hereby incorporated by reference herein.

### FIELD

The invention relates to a device equipped with an ion beam source for coating at least one substrate in a vacuum in a vacuum chamber.

### BACKGROUND

A device of this kind is used to treat substrates in discontinuous production methods using what is known as a batch process, in which at least one substrate or a plurality of substrates grouped together to form a batch are introduced into the treatment facility, where they are coated or surface-modified in some other way and then removed from the treatment facility. In batch operation, the same chamber is used for both introducing and discharging the substrate.

In contrast, in a continuous-flow facility, substrates are constantly introduced into such a facility one after the other, where they are treated and removed again. In order to load and unload the treatment facility with substrates, a separate input chamber and output chamber is used in facilities of this type. In contrast, in batch operation the closable inlet is used for both introducing and discharging the substrate.

Carriers are used as substrate holder receptacles or substrate holders for different substrates and types of facilities, which hold and transport a substrate or a plurality of substrates throughout the entire process. Carriers of this type often comprise a frame having holding elements as the substrate holder.

The substrate holders have different designs according to the type of substrate, so that the substrates can be held in the substrate holder in the horizontal, vertical or tilted position by the edge region such that as little of the substrate surface is covered as possible.

Sputtering methods, for example, are used to produce thin layers. A solid target is bombarded with an ion beam, causing individual atoms of the ions to be released from the target and condense on the substrate.

DE 10 2012 110 052 B3 relates to a batch facility for treating substrates, comprising at least one loading chamber, at least one processing chamber, carriers for holding and for transporting substrates, a treatment apparatus and a transport device. In order to reduce the amount of space required by the facility for large substrates, at least three carriers are connected by means of coupling elements.

DE 10 2012 111 338 A1 relates to a coating method for disc-shaped substrates having a substrate front and a substrate back. The substrate carrier is loaded into a coating facility together with the substrate. Following the coating process, the substrate carrier, together with the substrate, is unloaded from the coating facility.

DE 10 2014 103 877 A1 discloses a facility for treating substrates in a vacuum for the continuous-flow treatment of glass. The embodiment of this transport system and the embodiment of the vacuum chamber are aimed at stopping or preventing the back of the substrate from being coated when coaling or treating said substrate.

DE 694 00 404 T2 relates to a device for sputtering a metal material on a substrate. In this case, conveyor belts or air conveyor devices having rails are used, from which carriages comprising substrate carriers are suspended.

One disadvantage of the prior art is the considerably restricted suitability of such devices for substrates having a large main extension, since in substrates of this kind, the distances between the substrate and the ion beam source or the target that differ in certain regions can lead to different deposition rates. Furthermore, the beam of atomized target material strikes the surface of the substrate at different angles, which can also lead to an uneven formation of the layer thickness.

### SUMMARY

An aspect of the invention provides a device, comprising: an ion beam source configured to coat at least one substrate in a vacuum chamber, the vacuum chamber including an inlet that is closable in a pressure-tight manner using a closure apparatus, and through which inlet the at least one substrate can be fixed in the vacuum chamber in a substrate holder in a substrate holder receptacle, wherein the substrate can be removed from the substrate holder once the coating process has finished, wherein the substrate holder, together with the substrate, in the substrate holder receptacle, are configured to be reversibly movable in a translational manner inside the vacuum chamber, between one or more turning points using a motor-drivable transport apparatus of the device.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1 is a partially cut-out perspective view of the device according to the invention comprising a vacuum chamber and a coating unit;

FIG. 2 is an additional partially cut-out perspective view of the device shown in FIG. 1;

FIG. 3 is a plan view of the device; and

FIG. 4 is a cross section through the device.

### DETAILED DESCRIPTION

Proceeding from the art in the Background, an object of the invention is to make it possible to provide optimum, in particular homogenous coating, taking into consideration the respective dimensions and nature of the substrate.

An aspect of the invention relates to a device equipped with an ion beam source for coating at least one substrate in a vacuum in a vacuum chamber, which chamber comprises an inlet that can be closed in a pressure-tight manner by means of a closure apparatus and through which the at least one substrate can be fixed in the vacuum chamber in a substrate holder to a substrate holder receptacle, and can be removed therefrom once the coating process has finished.

The invention therefore provides a device in which the substrate holder comprising the substrate is designed to be reversibly movable, by means of a motor-drivable transport apparatus of the device, in a translational manner inside the vacuum chamber, between turning points either side of an opening, which points are in particular infinitely variable and through which opening the beam of atomized target material is fed in. This first makes it possible to also always coat elongate substrates with a constant layer thickness, whereby the substrate is moved past the opening at a predetermined speed. The distance between the opening and the plane of the movement axis is thereby always constant, and therefore undesirable, uneven distribution of the layer thickness is ruled out. In this case, the fact that it is in particular possible to variably adapt the turning points to the substrate is particularly advantageous since undesirable losses of the coating material, which may also lead to disadvantageous deposition on the back of the substrate, can be largely prevented as a result. Thus the distance between the turning points is in particular only just larger than the maximum dimension of the substrate in the substrate holder in the movement direction. In addition, the opening for the emergence of the beam of atomized target material is preferably in the region of the geometric center between the turning points.

A particularly promising embodiment of the invention is also achieved in that the speed of the traversing movement of, for example, the substrate holder receptacle connected to a carriage along a guide of the transport apparatus can be variably adjusted such that the coating is homogenously applied along the entire surface to be coated, the layer thickness in particular therefore being constant.

Furthermore, the traversing speed can, however, also be adapted in a particularly expedient manner in that a highly curved surface region of the substrate having a surface area that is larger than that of the adjacent regions is, for example, exposed to the beam of atomized target material together with the coating material by reducing the speed for a long time. The speed can therefore be varied in particular to achieve a homogenous layer buildup even in curved substrate surfaces.

In this case, the change in the speed of the substrate carrier is preferably constant and consistently repeats for each cycle. Of course, the speed and the change thereto can also be adjusted on the basis of detected measured values from the coating progress.

The device could be equipped with a plurality of openings for feeding-in the beam of atomized target material. On the contrary, is it particularly practical when the ion beam source and the vacuum chamber are only connected by a single opening for the beam of the atomized target material, along which the substrate is moved in an in particular horizontal orientation. As a result, coating is restricted to a single region of the substrate, and therefore the advance speed can be varied according to the region to which the coating is applied in each case. Undesirable effects on other regions of the substrate which may require a different exposure time are ruled out as a result.

Furthermore, according to another particularly advantageous embodiment, the opening can be delimited by an adjustable diaphragm, so that the distribution of the coating material can be optimally adapted to the shape and nature of the substrate. For example, the diaphragm can enclose an opening that is delimited by two oval diaphragm regions, in order to achieve a uniform volumetric flow rate from the target arranged so as to be rotated by 45°. This in particular ensures a volumetric flow rate which is homogenous across the entire opening cross section.

It has also proven to be particularly practical for the substrate holder to comprise a receptacle for a test substrate and for the device to be equipped with a sensor for detecting the optical properties of the test substrate. This makes it possible to detect the particular layer thickness either continuously or cyclically when carrying out the coating process. By using a test substrate, the optical properties of which are known, for this purpose, reliable conclusions can be drawn about the layer thickness achieved in each case on the substrate by changing the measured values. For example, on the basis of broadband monitoring for the test substrate, a spectral curve is determined which allows a rapid comparison of the target transmission curve with the determined actual transmission curve.

The carriage comprising the substrate holder in the substrate holder receptacle can be moved inside the vacuum chamber by means of various drive systems. A particularly expedient embodiment of the invention is in particular achieved when the transport apparatus comprises at least one guide formed in particular as a rail, along which the substrate holder is moved, either placed thereon or suspended therefrom. Upon reaching the turning points, the drive direction of the drive used herefor is reversed.

The carriage can be designed to receive the substrate. On the other hand, it has already proven to be particularly practical for the substrate holder to comprise an interlocking receptacle for fixing the substrate to opposite end faces. This prevents the substrate surface from being damaged by the substrate holder, since the substrate is fixed outside the region of the substrate intended for coating. In addition, the substrate can also be pivoted about its longitudinal axis, whereby the end-face fixings can be mounted so as to be rotatable about a common axis with a corresponding degree of freedom.

It is also particularly expedient for a plurality of vacuum pumps to be assigned to the vacuum chamber, at least two vacuum pumps being arranged either side of the opening in order to achieve a uniform flow inside the vacuum chamber during the suction process. An additional vacuum pump is arranged on the coating apparatus.

The substrate is always inserted into the vacuum chamber through the same inlet and is removed therefrom once coating has finished. It is highly recommended in this case for the closure apparatus to be designed as a sliding door or swing door, which is immovably fixed in the vacuum chamber by the vacuum, and therefore the closure apparatus does not require a lock. Instead, the sealing elements provided on the closure apparatus are subjected to stress by the vacuum such that the required degree of sealing is achieved and progressively increased. This simplifies handling of the device.

The invention is not restricted to a specific coating material. Instead, the device is suitable for use with a plurality of substances known per se. In order to make it possible to use the device is various ways, said device comprises a target holder which can be equipped with a plurality of targets and is designed to be fixable in different positions, for example designed to be rotatable, in order to select the desired target.

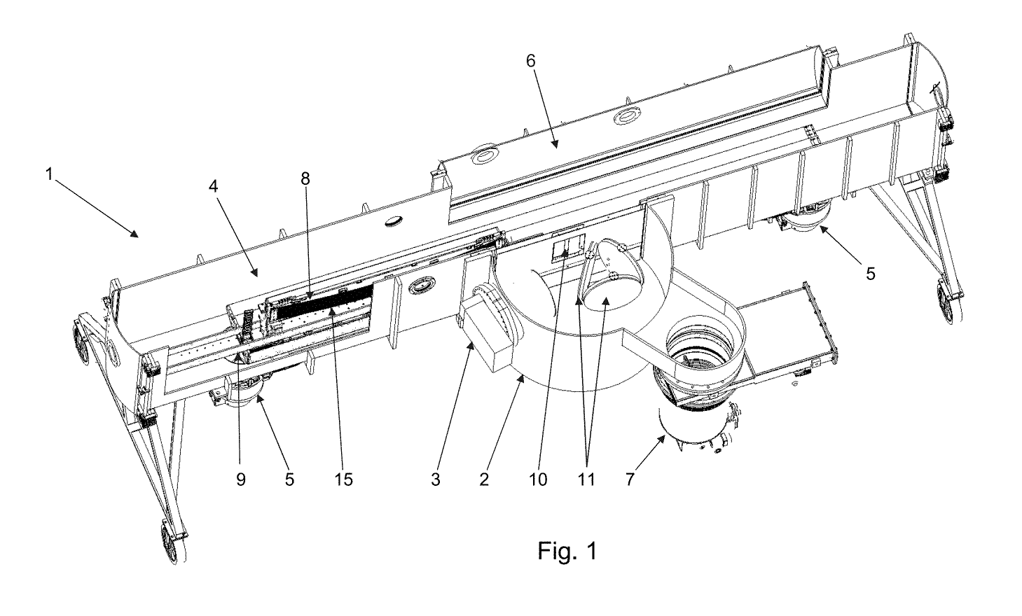

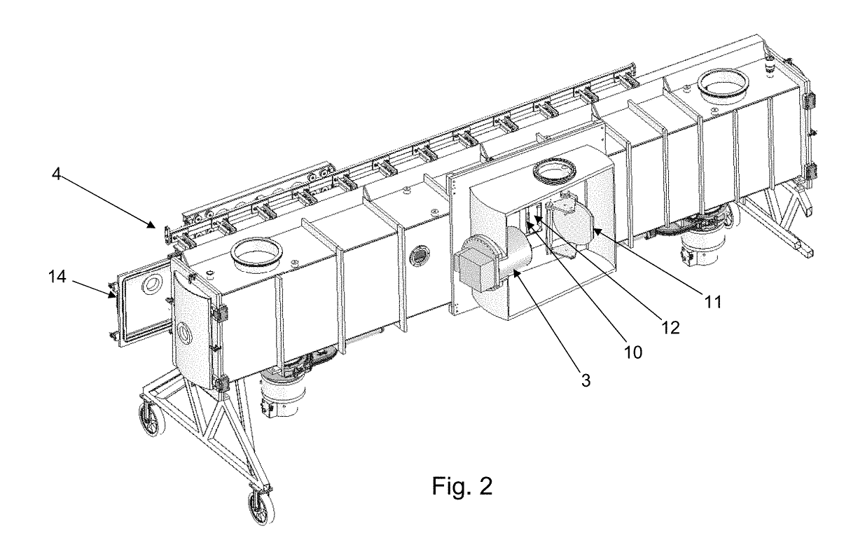

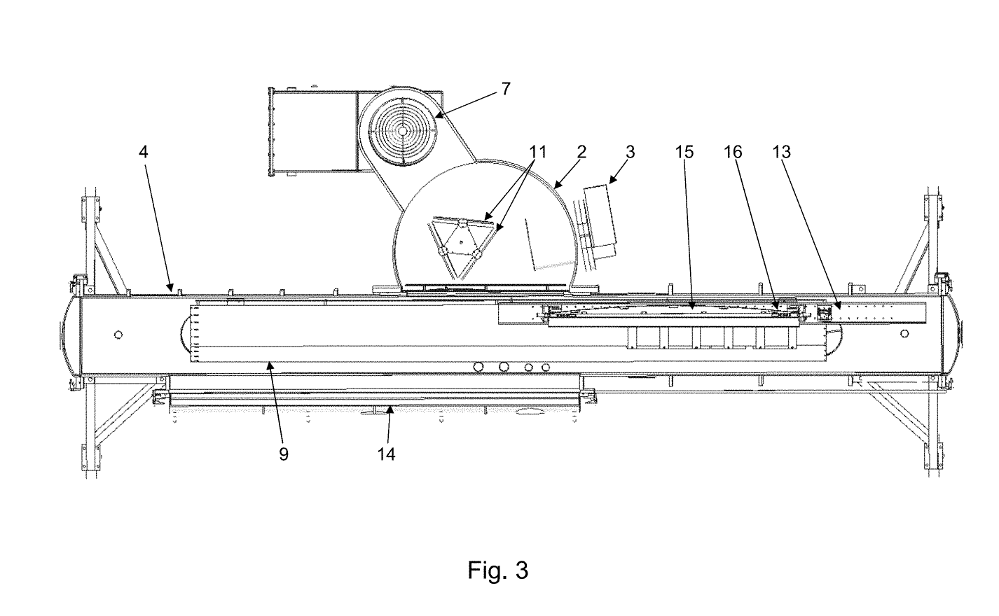

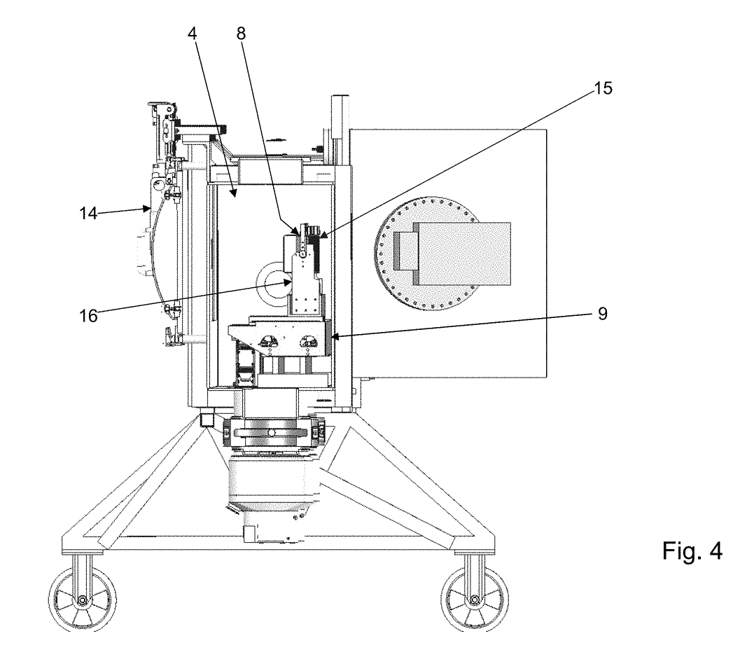

The device 1 according to the invention will be explained in more detail hereinafter, with reference to FIG. 1 to 4. The device 1 comprises a coating apparatus 2 having an ion beam source 3 for coating at least one substrate 15 according to the method of ion beam sputtering inside a vacuum chamber 4. The vacuum chamber 4 is equipped with a plurality of vacuum pumps 5 and has an overall length of at least 2.5 times the length of the substrate, i.e. of approximately 5 m for a substrate length of 2 m. An additional vacuum pump 7 is arranged on the coating apparatus 2. For the coating process, the substrate 15 fixed in a substrate holder 8 is introduced into the vacuum chamber 4 through an inlet 6, which can be closed by a closure apparatus 14 in the form of a pressure-tight sliding door, and can be fixed in a substrate holder receptacle 16 which is designed to be reversibly movable in a translational manner inside the vacuum chamber 4, between any selectable turning points, by means of a motor-drivable transport apparatus 9. In this case, the speed of the traversing movement between the turning points can be sped up or slowed down in predefined path portions in order to be able to adapt the exposure time of the beam of the atomized target material, which is directed at the substrate 15 through an opening 10 that connects the coating apparatus 2 to the vacuum chamber, to the particular nature of the substrate 15. The coating apparatus 2 comprises a target holder which can be equipped with a plurality of targets 11 and can be rotated in order to select the desired target 11. The substrate 15 can be coated with either a reflective or an antireflective coating, for example, which are designed as long rod lenses having a main extension of up to 2 m. The opening 10 is delimited by an adjustable diaphragm 12, by means of which a uniform volumetric flow rate to the surface of the substrate 15 can be achieved. In order to make the traversing movement as frictionless as possible, the transport apparatus 9 comprises a carriage 13 that is connected to the substrate holder receptacle 16.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B, and C” should be interpreted as one or more of a group of elements consisting of A, B, and C, and should not be interpreted as requiring at least one of each of the listed elements A, B, and C, regardless of whether A, B, and C are related as categories or otherwise. Moreover, the recitation of “A, B, and/or C” or “at least one of A, B, or C” should be interpreted as including any singular entity from the listed elements, e.g., A, any subset from the listed elements, e.g., A and B, or the entire list of elements A, B, and C.

### LIST OF REFERENCE NUMERALS

1 Device
2 Coating apparatus
3 Ion beam source
4 Vacuum chamber
5 Vacuum pump
6 Inlet
7 Vacuum pump
8 Substrate holder
9 Transport apparatus
10 Opening
11 Target
12 Diaphragm
13 Carriage
14 Closure apparatus
15 Substrate
16 Substrate holder receptacle

1: A device, comprising:
an ion beam source configured to coat at least one substrate in a vacuum chamber, the vacuum chamber including an inlet that is closable in a pressure-tight manner using a closure apparatus, and through which inlet the at least one substrate can be fixed in the vacuum chamber in a substrate holder in a substrate holder receptacle,
wherein the substrate can be removed from the substrate holder once the coating process has finished,
wherein the substrate holder, together with the substrate, in the substrate holder receptacle, are configured to be reversibly movable in a translational manner inside the vacuum chamber, between one or more turning points using a motor-drivable transport apparatus of the device.

2: The device of claim 1, wherein a distance between the turning points of translational movement is infinitely variable.

3: The device of claim 1, wherein, during movement between the turning points, a traversing movement speed can be controlled in one or more predetermined path portions.

4: The device of claim 1, further comprising:
a coating apparatus including the ion beam source,
wherein the coating apparatus and the vacuum chamber are only connected by a single opening for a beam of atomized target material, along which the substrate is moved in an in particular horizontal orientation.

5: The device of claim 7, wherein the single opening is delimited by an adjustable diaphragm.

6: The device of claim 1, wherein the substrate holder includes a receptacle configured to receive a test substrate, and
wherein the device includes a sensor configured to detect one or more optical properties of the test substrate.

7: The device of claim 1, wherein the motor-driven transport apparatus includes a guide.

8: The device of claim 1, wherein the motor-driven transport apparatus includes a mounted carriage including a substrate holder receptacle rigidly connected to the mounted carriage.

9: The device of claim 1, wherein the substrate holder includes an interlocking receptacle configured to fix the substrate to opposite end faces.

10: The device of claim 1, further comprising:
two or more vacuum pumps, assigned to the vacuum chamber.

11: The device of claim 1, wherein the closure apparatus is a sliding door, which is immovably fixed in the vacuum chamber by the vacuum.

12: The device of claim 1, further comprising:
a target holder that can be equipped with two or more targets,
wherein the target holder is configured to be fixable in various positions in order to select a desired target.

13: The device of claim 1, configured as a mobile unit including an undercarriage.

14: The device of claim 1, wherein the turning points are settable.

15: The device of claim 1, wherein a distance between the turning points of the translational movement is infinitely variable, depending on dimensions of the substrate.

16: The device of claim 1, wherein, during movement between the turning points, a traversing movement speed can be controlled in one or more predetermined path portions so as to constantly increase and/or decrease.

17: The device of claim 1, wherein the motor-driven transport apparatus includes a guide, in the form of a rail.

18: The device of claim 1, wherein the motor-driven transport apparatus includes two or more guides.

19: The device of claim 1, wherein the closure apparatus is a swing door, which is immovably fixed in the vacuum chamber by the vacuum.
